(19) United States
(12) Patent Application Publication
(10) Pub. No.: US 2012/0145078 A1
(43) Pub. Date: Jun. 14, 2012

(54) SHOWERHEAD INTEGRATING INTAKE AND EXHAUST

(75) Inventors: Chih-Yung Huang, Taichung City (TW); Ching-Chiun Wang, Miaoli County (TW); Chen-Der Tsai, Hsinchu County (TW); Wen-Tung Hsu, Yunlin County (TW); Fu-Ching Tung, Hsinchu City (TW); Chien-Chih Chen, Taichung City (TW); Yi-Tsung Pan, Hsinchu County (TW); Chien-Jen Sun, Hsinchu County (TW)

(73) Assignee: INDUSTRIAL TECHNOLOGY RESEARCH INSTITUTE, Hsinchu (TW)

(21) Appl. No.: 13/211,309

(22) Filed: Aug. 17, 2011

(30) Foreign Application Priority Data
Dec. 10, 2010 (TW) 99143375
Aug. 4, 2011 (TW) 100127734

(51) Int. Cl. C23C 16/455; B05B 1/14

(52) U.S. Cl. 118/715; 239/548

(57) ABSTRACT

A showerhead integrating intake and exhaust is provided for showering a gas. The showerhead at least includes a showerhead body that has a gas-active surface and a plurality of intake bores thereon. The showerhead body further includes a central exhaust vent disposed on the gas-active surface. The central exhaust vent may exhaust standing gas and further pre-exhaust byproduct from reaction process.

### CROSS-REFERENCE TO RELATED APPLICATION

This application claims the priority benefit of Taiwan application serial no. 99143375, filed on Dec. 10, 2010 and Taiwan application serial no. 100127734, filed on Aug. 4, 2011. The entirety of each of the above-mentioned patent applications is hereby incorporated by reference herein and made a part of this specification.

### TECHNICAL FIELD

The disclosure relates to a showerhead integrating intake and exhaust.

### BACKGROUND

Metal organic chemical vapor deposition (MOCVD) is one of the methods for performing an epitaxial process on a wafer. Currently, a showerhead is mostly adopted as the intake apparatus of MOCVD. However, the design of the showerhead usually causes holdup of the gas concentration in the center, such that this area can not be utilized and further affects the wavelength uniformity at the edge of the wafer. As the above phenomenon occurs in a chamber of small size, the control of uniformity becomes more difficult in the development of a large size chamber. That is, other than the gas holdup region in the center, the gas concentration closer to the extraction becomes lower as the path of the gas flow lengthens.

Therefore, patents related to improving the uniformity of the airflow field have been disclosed such as U.S. Pat. No. 7,138,336 B2 or U.S. Pat. No. 7,641,939 B2. The patents aforementioned adopt a showerhead for intake and a chamber with lateral exhaust to control the intake and exhaust of gas.

### SUMMARY

A showerhead integrating intake and exhaust is introduced herein. Other than solving the gas holdup in the showerhead, the showerhead of the disclosure can also balance a concentration distribution on a surface of a substrate and exhaust a byproduct from a reaction process.

A showerhead integrating intake and exhaust is introduced herein for showering a gas. The showerhead at least includes a showerhead body having a gas-active surface and a plurality of intake bores disposed on the gas-active surface. The showerhead body further includes a central exhaust vent disposed on a center of the gas-active surface.

In light of the foregoing, the intake and the exhaust of gas are both designed in the showerhead of the disclosure to extract the high concentration gas in the center of the chamber using a regional intake and exhaust showering technique for the concentration in the center and on the sides to be uniform. Also, the byproduct generated from the reaction can be exhausted first to prevent the byproduct from remaining in the chamber for too long so as to affect the reaction product such as generating an epitaxy of poor quality.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a three-D view illustrating a showerhead integrating intake and exhaust according to an exemplary embodiment.

FIG. 2A is a plan view illustrating a showerhead integrating intake and exhaust according to another exemplary embodiment.

FIG. 2B is a schematic cross-sectional diagram taken along line B-B in FIG. 2A.

FIG. 3A is a plan view illustrating a showerhead that a ratio of an area of the central exhaust vent to an area of the intake bores is smaller than 0.03.

FIG. 3B is a plan view illustrating a showerhead integrating intake and exhaust according to another exemplary embodiment.

FIG. 4 is a schematic cross-sectional diagram taken along line B′-B′ in FIG. 3B.

### DETAILED DESCRIPTION OF DISCLOSED EMBODIMENTS

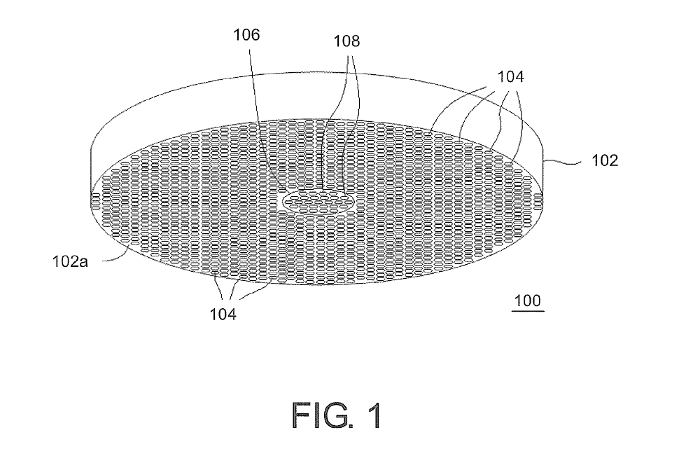

FIG. 1 is a three-D view illustrating a showerhead integrating intake and exhaust according to an exemplary embodiment.

Referring to FIG. 1, a showerhead 100 integrating intake and exhaust of the present exemplary embodiment at least includes a showerhead body 102 having gas-active surface 102a. Moreover, there are a plurality of intake bores 104 disposed on the gas-active surface 102a. In this exemplary embodiment, the showerhead body 102 includes a central exhaust vent 106 disposed on a center of the gas-active surface 102a. The central exhaust vent 106 is constituted by a plurality of exhaust bores 108, for example. The showerhead 100 is capable of showering gas for processes such as vacuum coating and the like.

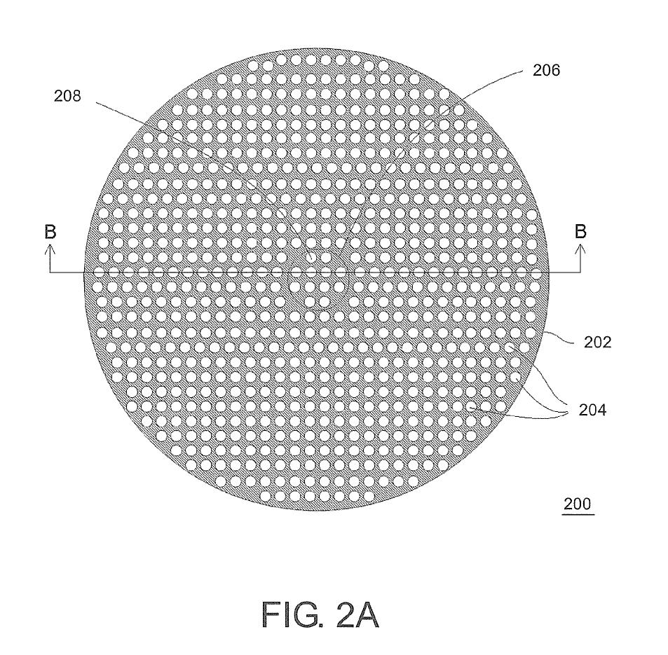

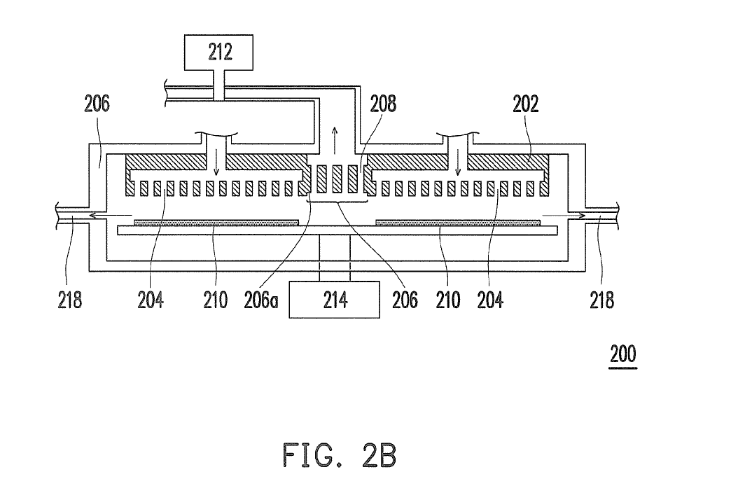

FIG. 2A is a plan view illustrating a showerhead integrating intake and exhaust according to another exemplary embodiment. FIG. 2B is a schematic cross-sectional diagram taken along line B-B in FIG. 2A.

Referring to FIG. 2A, a showerhead 200 integrating intake and exhaust of the present exemplary embodiment at least includes a showerhead body 202, and this drawing illustrates the gas-active surface of the showerhead body 202. The showerhead body 202 has a plurality of intake bores 204 and a central exhaust vent 206 disposed in the center of the gas-active surface. The central exhaust vent 206 is constituted by a plurality of exhaust bores 208, for example.

Referring to FIGS. 2A and 2B, the showerhead 200 is capable of showering gas on a plurality of substrates 210 and is suitable for processes such as vacuum coating and the like. For instance, a position of the central exhaust vent 206 and an arrangement of the substrates 210 are staggered. Moreover, arrows in FIGS. 2A and 2B represent a direction of airflow. Accordingly, an exhaust direction of the central exhaust vent 206 and an intake direction of the plurality of intake bores 204 are parallel, for example.

In the present embodiment, a ratio of an area of the central exhaust vent 206 to an area of the intake bores 204 ranges from 0.03 to 0.04, for instance. Also, an extraction end 206a of the central exhaust vent 206 may concave inward to the showerhead body 202 to prevent a gas being extracted from mixing with a gas being passed through the intake bores 204. In other words, when a location of the extraction end 206a of the central exhaust vent 206 is closer to the substrates 210 than the outlets of the intake bores 204 are, the performance of the central exhaust vent 206 may be affected.

In the present embodiment, at least one flow meter 212 is disposed to control exhaust amount of the central exhaust vent 206, for example. The air displacement of the central exhaust vent 206 has to be controlled to be less than the air flow passed from the intake bores 204. Moreover, the internal pressure of a reaction chamber 216 needs to be maintained consistently. In addition, the showerhead 200, for example, further includes a lift mechanism 214 to adjust a distance between the substrates 210 and the showerhead body 202. Further, processes such as coating is facilitated when an area of the showerhead body 202 is larger than a total area of the substrates 210, for example.

The showerhead 200 disposed in the reaction chamber 216 not only adopts the central exhaust vent 206 to balance the gas concentration in the center and the sides of the reaction chamber 216, but an extraction vent such as a lateral extraction vent 218 is designed in the reaction chamber 216 to perform the main extraction.

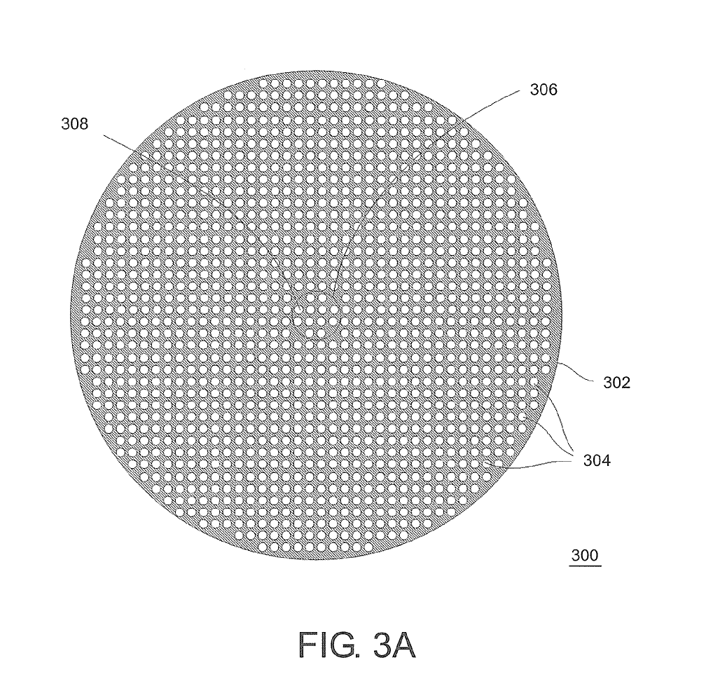

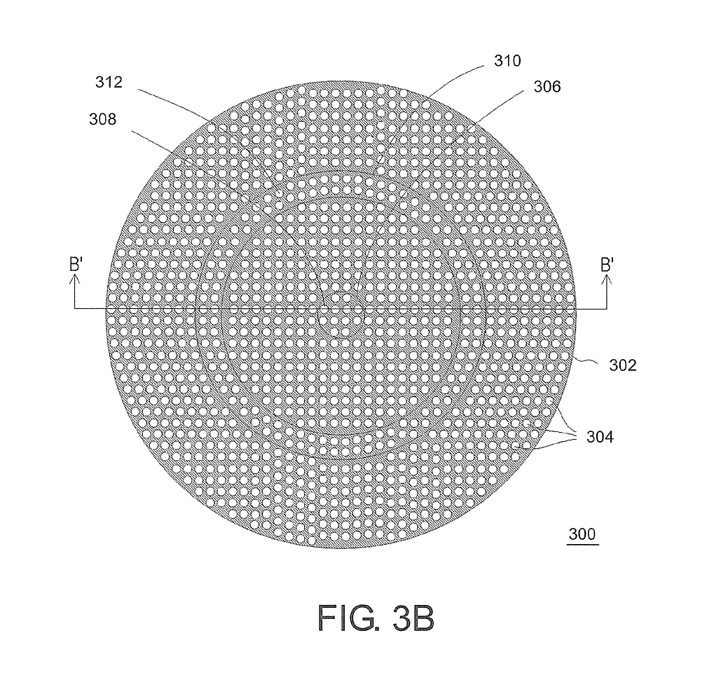

FIG. 3A is a plan view illustrating a showerhead that a ratio of an area of the central exhaust vent to an area of the intake bores is smaller than 0.03.

Referring to FIG. 3A, a showerhead 300 integrating intake and exhaust is similar to the showerhead 200 in the above exemplary embodiment in general. The showerhead 300 also includes a showerhead body 302 having a plurality of intake bores 304 and a central exhaust vent 306 with a plurality of exhaust bores 308 on the gas-active surface thereof. However, a ratio of an area of the central exhaust vent 306 to an area of the intake bores 304 is smaller than 0.03, and thus it is possible to sink the exhaust amount of the central exhaust vent 306. Therefore, the showerhead integrating intake and exhaust in this disclosure has another exemplary embodiment as shown in FIG. 3B.

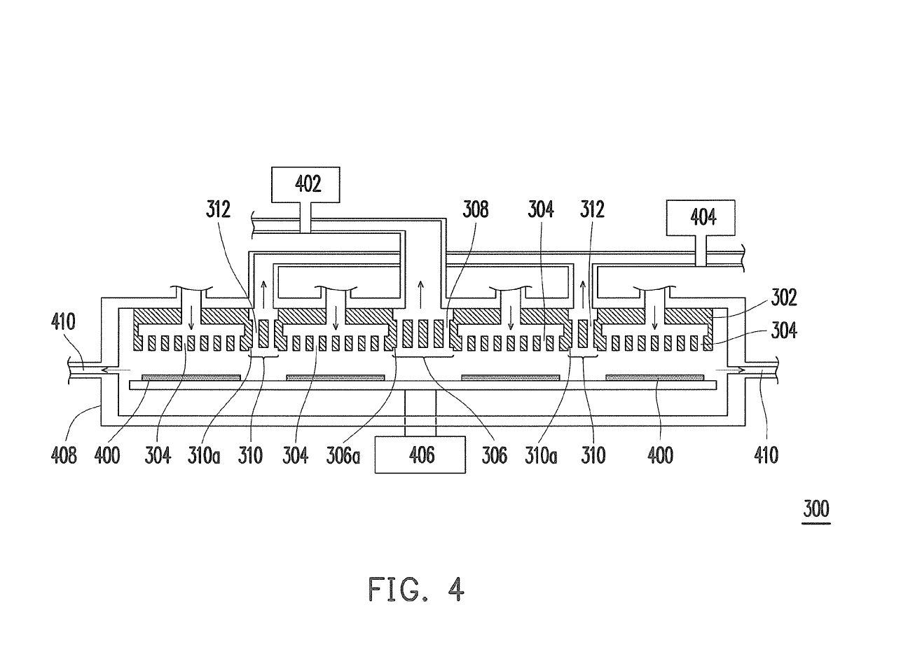

FIG. 3B is a plan view illustrating a showerhead integrating intake and exhaust according to yet another exemplary embodiment. FIG. 4 is a schematic cross-sectional diagram taken along line B′-B′ in FIG. 3B.

Referring to FIGS. 3B and 4, the showerhead 300 integrating intake and exhaust of the present exemplary embodiment is similar to the showerhead 300 in FIG. 3A. The difference between FIG. 3A and FIG. 3B is that the showerhead 300 integrating intake and exhaust in FIG. 3B further has at least one annular exhaust vent 310 designed in the showerhead body 302. The annular exhaust vent 310 is disposed concentrically with the central exhaust vent 306 as the center. The annular exhaust vent 310 is constituted by a plurality of second exhaust vents 312, for example. The distribution and size of the first exhaust vents 308 and the second exhaust vents 312 can be adjusted upon requirement. In one embodiment, the central exhaust vent 306 and the annular exhaust vent 310 both need to be staggered with the positions of a plurality of substrates 400 in FIG. 4. The showerhead 300 is capable of showering gas on the substrates 400 in large areas and is especially suitable for processes such as large-area vacuum coating and the like. The arrows in FIG. 4 represent the direction of airflow. That is, an exhaust direction of the central exhaust vent 306 and an intake direction of the intake bores 304 are parallel, and an exhaust direction of the annular exhaust vent 310 and an intake direction of the intake bores 304 are parallel, for example.

Referring to FIG. 4, an extraction end 306a of the central exhaust vent 306 and an extraction end 310a of the annular exhaust vent 310 are designed to concave inward to the showerhead body 302 to prevent a gas being extracted from mixing with a gas being passed through the intake bores 304. Moreover, a plurality of flow meters 402 and 404 may be further disposed in the showerhead 300 to control the exhaust amount of the central exhaust vent 306 and the annular exhaust vent 310 respectively.

In the present exemplary embodiment, the showerhead 300 further includes a lift mechanism 406 to adjust a distance between the substrates 400 and the showerhead body 302, for example. Furthermore, processes such as coating is facilitated providing that an area of the showerhead body 302 is larger than a total area of the substrates 400, for example. Moreover, in the reaction chamber 408, extraction devices such as lateral extraction vents 410 and the like may be installed, for instance.

In summary, the showerhead of the disclosure integrates intake and exhaust at the same time. Thus, the concentration in the center and the sides of the chamber is consistent through the showering technique of regional intake and exhaust. The byproduct generated from the reaction process can also be extracted first in the disclosure to prevent the byproduct from residing in the chamber for too long so as to affect the reaction results such as the generation of poor quality epitaxy during vacuum coating. The showerhead of the disclosure further includes properties such as simple structure, low processing cost, and easy maintenance.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A showerhead integrating intake and exhaust, for showering a gas, comprising at least one showerhead body, and the showerhead body has a gas-active surface and a plurality of intake bores disposed on the gas-active surface, wherein
the showerhead body further comprises a central exhaust vent disposed on a center of the gas-active surface.

2. The showerhead integrating intake and exhaust as claimed in claim 1, wherein a ratio of an area of the central exhaust vent to an area of the intake bores ranges from 0.03 to 0.04.

3. The showerhead integrating intake and exhaust as claimed in claim 1, wherein the central exhaust vent is constituted by a plurality of exhaust bores.

4. The showerhead integrating intake and exhaust as claimed in claim 1, wherein an extraction end of the central exhaust vent concaves inward to the showerhead body.

5. The showerhead integrating intake and exhaust as claimed in claim 1, wherein an exhaust direction of the central exhaust vent and an intake direction of the plurality of intake bores are parallel.

6. The showerhead integrating intake and exhaust as claimed in claim 1, wherein a ratio of an area of the central exhaust vent to an area of the intake bores is smaller than 0.03.

7. The showerhead integrating intake and exhaust as claimed in claim 6, the showerhead body further comprises at least one annular exhaust vent disposed concentrically with the central exhaust vent as a center.

8. The showerhead integrating intake and exhaust as claimed in claim 7, wherein the annular exhaust vent is constituted by a plurality of exhaust bores.

9. The showerhead integrating intake and exhaust as claimed in claim 7, wherein an extraction end of the annular exhaust vent concaves inward to the showerhead body.

10. The showerhead integrating intake and exhaust as claimed in claim 7, wherein an exhaust direction of the annular exhaust vent and an intake direction of the plurality of intake bores are parallel.

11. The showerhead integrating intake and exhaust as claimed in claim 7, further comprising at least one flow meter to control an exhaust amount of the central exhaust vent or the annular exhaust vent.

12. The showerhead integrating intake and exhaust as claimed in claim 7, wherein the showerhead is for showering the gas on a plurality of substrates.

13. The showerhead integrating intake and exhaust as claimed in claim 12, wherein a position of the annular exhaust vent and an arrangement of the substrates are staggered.

14. The showerhead integrating intake and exhaust as claimed in claim 12, further comprising a lift mechanism to adjust a distance between the substrates and the showerhead body.

15. The showerhead integrating intake and exhaust as claimed in claim 12, wherein an area of the showerhead body is larger than a total area of the substrates.

16. The showerhead integrating intake and exhaust as claimed in claim 1, further comprising at least one flow meter to control an exhaust amount of the central exhaust vent.

17. The showerhead integrating intake and exhaust as claimed in claim 1, wherein the showerhead is for showering the gas on a plurality of substrates.

18. The showerhead integrating intake and exhaust as claimed in claim 17, wherein the central exhaust vent and an arrangement of the substrates are staggered.

19. The showerhead integrating intake and exhaust as claimed in claim 17, further comprising a lift mechanism to adjust a distance between the substrates and the showerhead body.

20. The showerhead integrating intake and exhaust as claimed in claim 17, wherein an area of the showerhead body is larger than a total area of the substrates.
